(19) United States
(12) Patent Application Publication
(10) Pub. No.: US 2013/0275086 A1
(43) Pub. Date: Oct. 17, 2013

(54) METHOD AND MAGNETIC RESONANCE APPARATUS TO IDENTIFY A NOISE VOLUME FOR A MAGNETIC RESONANCE EXAMINATION

(71) Applicants: David Grodzki, Erlangen (DE); Lars Lauer, Neunkirchen (DE)

(72) Inventors: David Grodzki, Erlangen (DE); Lars Lauer, Neunkirchen (DE)

(21) Appl. No.: 13/862,701

(22) Filed: Apr. 15, 2013

(30) Foreign Application Priority Data
Apr. 16, 2012 (DE) 102012206198.3

(51) Int. Cl. G01R 33/44

(52) U.S. Cl. CPC G01R 33/44
USPC 702/182

(57) ABSTRACT

In a method and magnetic resonance apparatus to determine and/or adjust a noise volume for a magnetic resonance examination, a selection of a magnetic resonance sequence for the magnetic resonance examination of a subject to be examined hereby is made and an automatic calculation of an expected noise volume for the magnetic resonance examination is made in a volume determination unit using protocol parameters of the selected magnetic resonance sequence. Information about the expected volume is provided to an operator via a user interface.

### BACKGROUND OF THE INVENTION

1. Field of the Invention

The present invention concerns a method to identify (determine and/or adjust) a noise volume for a magnetic resonance examination, by selection of a magnetic resonance sequence for the magnetic resonance examination of a subject to be examined.

2. Description of the Prior Art

Magnetic resonance examinations are typically associated with a high noise level for the patient, with noises at a level of 100 dB(A) and more being caused during the magnetic resonance examination. These loud noises are primarily caused by rapidly changing gradient fields that lead to distortions and/or oscillations in the gradient coil unit of the magnetic resonance device (scanner) and/or due to transfer of energy to the housing of the magnetic resonance device, for example.

In order to avoid an uncomfortably high noise exposure for the patient, most often the patient must wear hearing protection during the magnetic resonance examination. However, not all disruptive noises can be eliminated by the hearing protection, such that loud and/or disruptive noises still reach the patient. Resting comfort for the patient is additionally impaired due to the wearing of hearing protection.

### SUMMARY OF THE INVENTION

An object of the present invention is to provide a method and an apparatus that enable effective countermeasures for noise suppression to be taken depending on a selected magnetic resonance sequence.

The invention encompasses a method to determine and/or adjust a volume for a magnetic resonance examination, that includes the following steps. A magnetic resonance sequence for the magnetic resonance examination of a subject to be examined is selected. An expected volume for the magnetic resonance examination is calculated in a computerized volume determination unit using protocol parameters of the selected magnetic resonance sequence. Information identifying the expected volume is provided to an operator via a user interface in communication with the volume determination unit.

The calculation of the expected volume, and the subsequent provision of the expected volume to the operator enable the operator to already take suitable countermeasures in a planning phase of the magnetic resonance examination, for example, to reduce the expected volume so that a lower noise exposure to the patient is achieved. In addition, a user-friendly presentation of the expected volume can be achieved.

The method according to the invention preferably is executed during preparation of the diagnostic magnetic resonance examination, for example during a planning phase that precedes the diagnostic magnetic resonance examination, such that measures for a noise reduction can already be taken in the planning phase and/or in the preparation. At the same time, with the selection of the magnetic resonance sequence by the operator, a measurement protocol for the planned magnetic resonance examination is retrieved and/or generated by a control unit, in which individual parameter settings for the selected magnetic resonance sequence can be adjusted within the measurement protocol. In this context, “volume” means a volume (audible level) of noises of an interaction between the gradient coil unit of the magnetic resonance device (scanner) and a magnet unit (in particular the housing of the magnet unit) of the magnetic resonance device in a measurement operation for the magnetic resonance examination. An “expected volume” means a volume of noises that occur with a high probability during a measurement (data acquisition) procedure (in which the selected magnetic resonance sequence with the preset sequence parameters is used) due to interactions between the gradient coil unit and additional components of the magnet unit of the magnetic resonance device. The information about the expected volume preferably a value, such as a decibel value, of the expected volume. The subject to be examined is a human or animal organism, in particular a human patient. The volume determination unit has a processor and/or computer programs that are required for the determination and/or calculation of the expected volume. The calculation of the expected volume takes place independently and/or automatically in the volume determination unit.

In accordance with the invention, the expected volume is adjustable, so an adaptation and/or adjustment of the magnetic resonance examination can be achieved with regard to the expected volume.

In an embodiment of the invention, a desired value of the expected volume is adjustable. The desired value can be entered manually as an input by an operator via the user interface. A user-defined adjustment of a volume during the measurement operation with the selected magnetic resonance sequence can be achieved in such a manner, and a volume regulation can already be achieved during the planning phase. A maximum desired value of the expected volume can be manually adjusted or set by the operator via the user interface.

An adaptation of parameter settings of the selected magnetic resonance sequence can take place automatically via the volume determination unit using the set desired value of the expected volume, and a calculation of the expected volume with the modified parameter settings subsequently takes place again for the selected magnetic resonance sequence by means of the volume determination unit. A greater increase in comfort for the user can be achieved in such a manner by the expected volume being set automatically to a desired value for the planned magnetic resonance examination, and thus a simple volume setting can be achieved for the operator. Furthermore, noise emission during the magnetic resonance examination can advantageously be reduced for the patient, so the well-being and comfort of the patient during the magnetic resonance examination can be increased.

In this context, “parameter settings for the selected magnetic resonance sequence” are timing parameters and/or sequence parameters. Furthermore, an “independent adaptation by the volume determination unit” means an automatic adaptation by the volume determination unit, without repeated manual interactions by the operator being necessary for this purpose.

If the adjustment of the expected volume takes place manually via the user interface by a selection and/or adjustment of parameter settings for the selected magnetic resonance sequence, a desired expected volume can be set by the operator depending on the selected parameter settings, and/or a value of the expected volume can be adapted to a desired value of the expected volume.

In a further embodiment, a selection of parameter settings for the selected magnetic resonance sequence depending on the desired value of the expected volume is provided by the volume determination unit for a manual selection and/or a manual adjustment of parameter settings of the selected magnetic resonance sequence. This prevents a manual selection or adjustment by the operator of parameter settings that would lead to a higher value for the expected volume than the desired value for the expected volume during the planning of the selected magnetic resonance sequence. Parameter settings that would lead to a larger value for the expected volume than the desired value of the expected volume thus are no longer available for use by the operator in the adjustment and/or adaptation of the measurement protocol for the selected magnetic resonance sequence, i.e. their ability to be manually selected is automatically prohibited and/or blocked by the volume determination unit.

In a further embodiment, at least two measurement options with the respective expected volume are displayed for the selected magnetic resonance sequence, wherein a measurement option can be manually selected from the at least two measurement options for the selected magnetic resonance sequence. The display of the at least two measurement options and/or a generation of the at least two measurement options for the selected magnetic resonance sequence is advantageously generated automatically by means of the volume determination unit. A particularly quick adjustment of a desired value of the expected volume for the selected magnetic resonance sequence can take place via this embodiment of the invention. A measurement protocol with already adjusted parameter settings for the selected magnetic resonance sequence is retrieved by means of the selection of a measurement option.

In a further embodiment of the invention the expected volume of the selected magnetic resonance sequence is determined using parameter settings stored in a database, with which parameter settings a volume value is respectively associated, so a preferred time-saving determination of the expected volume can be achieved and the planning of the magnetic resonance examination can be implemented in a time-saving manner. In addition, the expected volume for the selected magnetic resonance sequence or, respectively, for the parameter settings of the selected magnetic resonance sequence that are made by the operator can hereby be displayed and/or presented to said operator particularly quickly. Alternatively or additionally, the expected volume can be determined by means of a mathematical estimation, wherein the mathematical estimation includes an aliasing of frequency spectra of a gradient coil unit of the magnetic resonance device with a transfer function of a magnet unit of said magnetic resonance device, for example as this is described by X. Chen et al.: “Experimental reduction of acoustic noise through cancellation of impulsive forces” Proc. International Society for Magnetic Resonance in Medicine 16, 2008.

An optical output of the information of the expected volume advantageously takes place via the user interface so that the operating planning the magnetic resonance examination is informed of the expected volume immediately after a selection is made (which selection particularly preferably takes place by means of the same user interface).

The invention also encompasses a magnetic resonance apparatus with a user interface and a volume determination unit to execute the method described above to determine and/or adjust a noise volume for a magnetic resonance examination. Countermeasures to decrease the expected volume can already be taken in a planning phase of the magnetic resonance examination, and the expected volume can be reduced so that (for example) such a lower exposure for the patient is achieved. In addition, a user-friendly presentation of the expected volume can be achieved.

The magnetic resonance device has a memory unit in which a database is stored that includes parameters that are selectable for individual magnetic resonance sequences, with a volume value being associated with each of the parameter settings. A preferred, time-saving determination of the expected volume can be achieved by the use of the database in a determination of the expected volume. In addition, the expected volume for the selected magnetic resonance sequence or for the parameter settings of the selected magnetic resonance sequence that are made by the operator can be displayed and/or presented to said operator particularly quickly.

In an embodiment of the apparatus of the invention, the user interface has at least one optical output for optical presentation of information of an expected volume, so the operator who is planning the magnetic resonance examination can be informed of the expected volume immediately after a selection is made, which preferably takes place via the same user interface.

### BRIEF DESCRIPTION OF THE DRAWINGS

FIG. 1 is a flowchart of an embodiment of the method according to the invention to determine and/or adjust a noise volume for a magnetic resonance examination.

FIG. 2 schematically illustrates an embodiment of the apparatus according to the invention.

### DESCRIPTION OF THE PREFERRED EMBODIMENTS

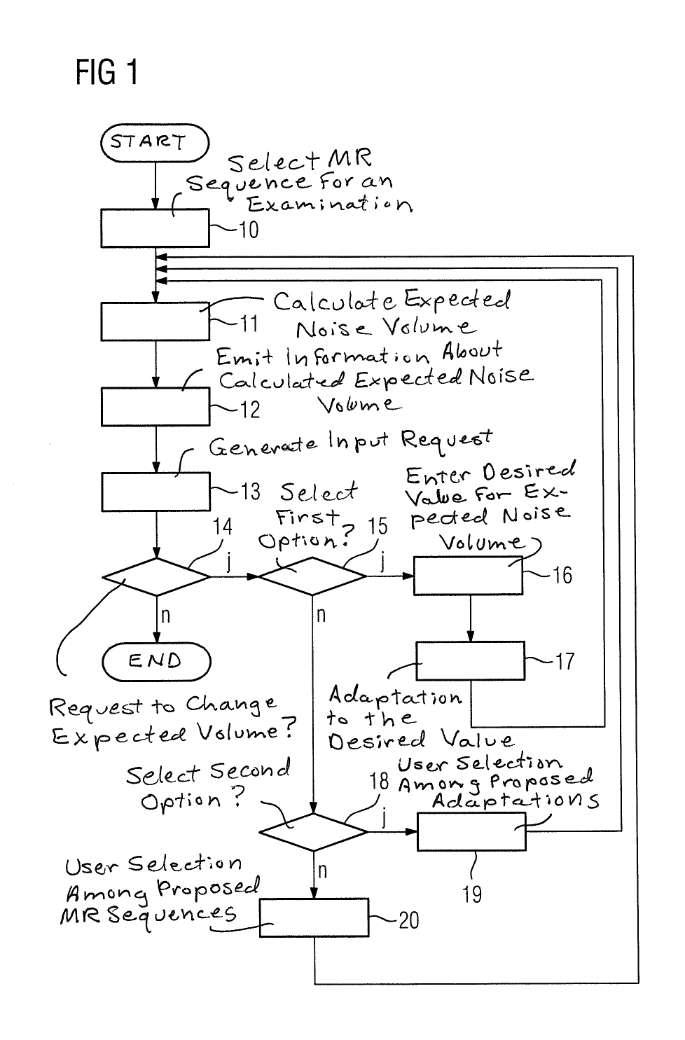

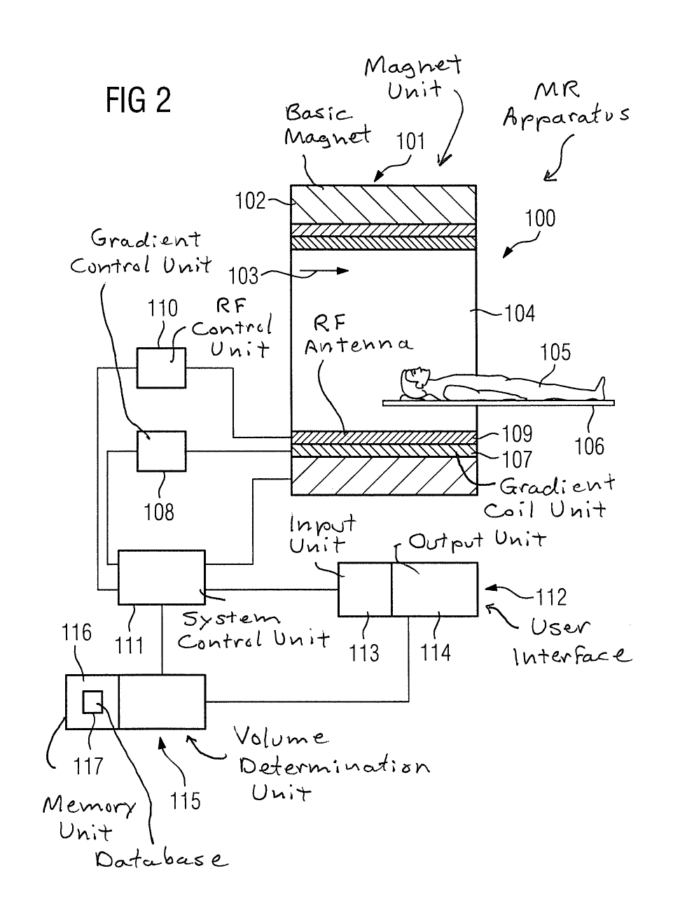

A method according to the invention to determine and/or adjust an expected noise volume for a magnetic resonance examination is shown in FIG. 1, which is explained in conjunction with the apparatus shown in FIG. 2. The method according to the invention preferably takes place during a planning of a pending magnetic resonance examination of a subject to be examined, for example a patient 105. In this planning of the magnetic resonance examination, in a first method step at the beginning of the method a selection 10 of a magnetic resonance (MR) sequence is made manually by an operator at a user interface 112 of a magnetic resonance device 100. The user interface 112 includes an input unit 113 (for example a keyboard and/or a touchscreen, etc.) and an output unit 114 (a monitor, for example). The operator thus makes his or her selection 10 of the magnetic resonance sequence with the input unit 113.

In response to the selection of the magnetic resonance sequence by the operator, a measurement protocol for the planned magnetic resonance examination is retrieved and/or generated by a control unit 111 of the magnetic resonance device 100, and individual parameter settings for the selected magnetic resonance sequence can be adjusted within the measurement protocol.

After the operator has made the selection 10 of the magnetic resonance sequence for the pending magnetic resonance examination, in a further method step a calculation 11 of an expected volume for the pending magnetic resonance examination is made independently and/or automatically by a volume determination unit 115 of the magnetic resonance device 100. The noise determination unit 115 is connected via a data line with the control unit 111 for a data exchange between the control unit 111 and the noise determination unit 115.

The calculation 11 of the expected volume takes place using initial, preset protocol parameters of the selected magnetic resonance sequence. For this purpose, the volume determination unit 115 has a processor and a memory unit 116 in which are stored software programs for the implementation of the calculation 11 and for controlling the method according to the invention. Furthermore, the volume determination unit 115 has a database 117 that is likewise stored in the memory unit 116. The database 117 contains the individual parameter settings that can be selected for the individual magnetic resonance sequences. A volume value is associated with each these parameter settings in this database 117, such that the expected volume for the selected magnetic resonance sequence can be calculated by the volume determination unit 115 using the associated volume values for the selected parameter settings.

Alternatively or additionally, the expected volume can also be determined by a mathematical estimation for respective parameter settings by the volume determination unit 115. Such a mathematical estimation includes a mathematical aliasing of frequency spectra of a gradient coil unit 107 of the magnetic resonance device 100 with a transfer function of a magnet unit 101 of the magnetic resonance device 100.

After the calculation 11 of the volume, an output 12 of information about the expected volume for the selected magnetic resonance sequence with the currently set parameter settings takes place in a further method step. The output 12 takes place via the user interface 112, such as optically at the output unit 114 (in particular a monitor of the user interface 112). The expected volume is thus immediately presented so as to be visible to the operator.

In a further method workflow, the possibility exists for the operator to adapt or adjust the expected volume of the selected magnetic resonance sequence. Multiple variants are provided to the operator. For this purpose, an input request is initially generated by the volume determination unit 115 in a generation step 13, by means of which input request the operator can change the expected volume for the selected magnetic resonance sequence. Following this, a first query 14 takes place as to whether the operator wants to change the expected volume, which the operator communicates as a user input via the user interface 112.

If and when a change to the expected volume is provided by the operator, an additional queries 15 and 18 are made by the volume determination unit 115 as to what changes the operator would like to make to modify and/or adapt the expected volume to settings of the selected magnetic resonance sequence or to the measurement protocol that is therefore selected for the chosen magnetic resonance sequence.

If a first option is selected by the operator in query 15, in a further method step 16 the operator can make an input via the user interface 112 of a desired value for the expected volume of the selected magnetic resonance sequence. The desired value can be formed by a maximum value of the expected volume of the selected magnetic resonance sequence by itself and/or by a reference value that—assuming small deviations that are preferably in a range of at most 5% of the desired value, and particularly preferably of at most 3% of the desired value—should be reached in the creation and/or adaptation of the measurement protocol.

As soon as a desired value has been entered by the operator, an adaptation 17 of parameter settings for the selected magnetic resonance sequence is made automatically by the volume determination unit 115 in a further method step using the set desired value of the expected volume. The calculation 11 of the expected volume for the selected magnetic resonance sequence subsequently takes place again with the modified parameter settings. An output 12 additionally takes place again, in particular a display and/or presentation to the operator of the expected volume for the selected magnetic resonance sequence with the modified parameter settings by means of the output unit 114. In addition to this, the modified parameter settings can hereby also communicated to the operator via the output means 114 so that the operator has the possibility to change the desired value again in the event that parameter settings that are unwanted by the operator have been selected by the volume determination unit 115.

If the first option is not selected by the operator in query 15, in a further query 18 the operator can select a second option to adjust and/or adapt the volume to be examined for the selected magnetic resonance sequence. In this second option, a selection and/or adjustment 19 of parameter settings for the selected magnetic resonance sequence can be performed by the operator in a further method step 19. Using these modified parameter settings, a calculation 11 of the expected volume for the selected magnetic resonance sequence takes place again with the modified parameter settings. By means of the user interface 112, an output 12 (in particular a display and/or presentation) to the operator of the expected volume for the selected magnetic resonance sequence with the modified parameter settings subsequently takes place again by means of the output unit 114. The method steps of the selection and or adjustment 18 of parameter settings for the selected magnetic resonance sequence, the calculation 11 of the expected volume for the selected magnetic resonance sequence with the modified parameter settings, and the output 12 (in particular a display and/or presentation) of the expected volume for the selected magnetic resonance sequence with the modified parameter settings can be repeated until a desired expected volume is achieved.

Insofar as a desired value of the expected volume for the selected magnetic resonance sequence has already been entered and/or selected by the operator during the method, before the query 18, the operator can additionally make the modification and or adjustment 19 of the parameter settings for the selected magnetic resonance sequence. The operator is assisted by the volume determination unit 115, by the volume determination unit 115 presenting to the operator as selectable those parameter settings only those that, upon selection, lead to a volume value for the selected magnetic resonance sequence that is smaller than or equal to the desired value of the expected volume that is entered by the operator for the selected magnetic resonance sequence. As soon as an adjustment of the parameter settings to be adjusted has been modified, the calculation 11 of the expected volume for the selected magnetic resonance sequence takes place again with the modified parameter settings. In addition to this, the output 12 (in particular a display and/or presentation) to the operator of the expected volume for the selected magnetic resonance sequence with the modified parameter settings takes place again at the output unit 114.

If the second option is not selected by the operator in the further query 18, a third option for adjustment of the expected volume of the selected magnetic resonance sequence is provided to the operator. In this third option, in a further method step 20 at least two measurement options for the selected magnetic resonance sequence are displayed to the operator via the user interface 112 of the volume determination unit 115. These measurement options have different parameter settings for the selected magnetic resonance sequence. Using these parameter settings, in the method step 11 the volume determination unit 115 calculates the expected volume for the respective measurement option and communicates said expected volume to the operator in the method step 12 using a graphical display and/or presentation. These displayed measurement options can additionally be linked to a desired value of the expected volume for the selected magnetic resonance sequence, the desired value being entered by the operator.

Furthermore, the individual variants to adjust and/or adapt the volume of the selected magnetic resonance sequence can be combined with one another and/or a switch can be made between the individual variants at any time until the desired volume of the selected magnetic resonance sequence is achieved.

A magnetic resonance apparatus 100 according to the invention is schematically shown in FIG. 2. The magnetic resonance apparatus 100 has a magnet unit 101 with a basic magnet 102 to generate a strong and in particular constant basic magnetic field 103. In addition to this, the magnetic resonance device 100 has a cylindrical receptacle region 104 to receive the patient 105, wherein the receptacle region 104 is enclosed by the magnet unit 101 in a circumferential direction. The patient 105 can be moved into the receptacle region 104 by means of a patient bed 106 of the magnetic resonance device 100. For this purpose, the patient bed 106 is arranged so as to be movable within the magnetic resonance device 100.

The magnet unit 101 furthermore has a gradient coil unit 107 to generate magnetic field gradients that are used for a spatial coding during an imaging. The gradient coil unit 107 is controlled by a gradient control unit 108. Furthermore, the magnet unit 101 has a radio-frequency (RF) antenna 109 and a radio-frequency antenna unit 110 to excite a polarization that arises in the basic magnetic field 103 generated by the basic magnet 102. The radio-frequency antenna 109 is controlled by the radio-frequency control unit 110 and radiates radio-frequency magnetic resonance sequences into an examination space that is essentially formed by the receptacle region 104. The magnetization is deflected out of its steady state.

The magnetic resonance device 100 has a system control unit 111 (formed by a computer) to control the basic magnet 102, the gradient control unit 108, and to control the radio-frequency antenna unit 110. The computer centrally controls the magnetic resonance device 100, for example the implementation of a predetermined imaging gradient echo sequence.

Furthermore, the magnetic resonance device 100 has the volume determination unit 115 that, in the present exemplary embodiment, is fashioned separately from the system control unit 111. In an alternative embodiment of the invention, the volume determination unit 115 can be embodied in the control unit 111 of the magnetic resonance device 100.

Although modifications and changes may be suggested by those skilled in the art, it is the intention of the inventor to embody within the patent warranted hereon all changes and modifications as reasonably and properly come within the scope of his contribution to the art.

We claim as our invention:

1. A method to identify a noise volume associated with a magnetic resonance (MR) data acquisition procedure, comprising:
entering a designation, into a computerized processor, of an MR sequence to be implemented by an MR data acquisition unit in order to acquire MR data from a subject in the MR data acquisition unit, said MR sequence defining protocol parameters used to operate said MR data acquisition unit in order to execute said MR sequence;
in said processor, automatically calculating, using said protocol parameters, in expected noise volume produced by components of said MR data acquisition unit upon execution of said MR sequence; and
at a user interface in communication with said processor, presenting information describing said expected volume in a humanly perceptible form.

2. A method as claimed in claim 1 wherein said processor is configured to adjust said expected volume dependent on a manual input made via said user interface.

3. A method as claimed in claim 2 wherein said processor is configured to adjust said expected volume dependent on a desired value of the expected volume manually entered via said user interface.

4. A method as claimed in claim 3 comprising adapting said protocol parameters automatically dependent on said desired value of said expected volume by implementing a re-calculation of said expected volume with modified parameter settings dependent on said desired value.

5. A method as claimed in claim 2 comprising, via said user interface, automatically presenting a selection of settings for said protocol parameters from which a user selects said modified parameter settings.

6. A method as claimed in claim 1 comprising, via said user interface, providing a user with at least two options for adjusting said expected noise volume.

7. A method as claimed in claim 1 comprising storing, in an electronic memory, a plurality of different sets of parameter settings for said protocol parameters each with a respective volume value associated therewith, and calculating said expected volume by accessing said memory to retrieve and use the volume value respectively associated with parameter settings for the designated MR sequence.

8. A method as claimed in claim 1 comprising calculating said expected volume as a mathematical estimation including an aliasing of frequency spectra of a gradient coil of said MR data acquisition unit with a transfer function of a magnet unit of said MR data acquisition unit.

9. A method as claimed in claim 1 comprising presenting said information at said user interface as an optical display.

10. A magnetic resonance (MR) apparatus comprising:
an MR data acquisition unit;
a computerized processor having a user interface configured to allow manual entry into said processor of an MR sequence to be implemented by said MR data-acquisition unit in order to acquire MR data from a subject in the MR data acquisition unit, said MR sequence defining protocol parameters used to operate said MR data acquisition unit in order to execute said MR sequence;
said processor being configured to automatically calculate, using said protocol parameters, in expected noise volume produced by components of said MR data acquisition unit upon execution of said MR sequence; and
said processor being configured to present information describing said expected volume in a humanly perceptible form at said user interface.

11. An apparatus as claimed in claim 10 comprising an electronic memory in which a plurality of different sets of parameter settings for said protocol parameters are stored, each with a respective volume value associated therewith in said memory, and wherein said processor is configured to calculate said expected volume by accessing said memory to retrieve and use the volume value respectively associated with parameter settings for the designated MR sequence.

12. An apparatus as claimed in claim 10 wherein said processor is configured to calculate said expected volume as a mathematical estimation including an aliasing of frequency spectra of a gradient coil of said MR data acquisition unit with a transfer function of a magnet unit of said MR data acquisition unit.

13. An apparatus as claimed in claim 10 wherein said processor is configured to present said information at said user interface as an optical display.
